(19) United States
(12) Patent Application Publication
(10) Pub. No.: US 2025/0224884 A1
(43) Pub. Date: Jul. 10, 2025

(54) SELF-REFRESH EXIT DETECTION FOR MEMORY DEVICES

(71) Applicant: Micron Technology, Inc., Boise, ID (US)

(72) Inventors: Melissa I. Uribe, El Dorado Hills, CA (US); Aaron P. Boehm, Boise, ID (US); Steffen Buch, Munich (DE); Scott E. Schaefer, Boise, ID (US)

(21) Appl. No.: 18/984,753

(22) Filed: Dec. 17, 2024

Related U.S. Application Data
(60) Provisional application No. 63/619,179, filed on Jan. 9, 2024.

(51) Int. Cl. G06F 3/06; G11C 11/406

(52) U.S. Cl. CPC G06F 3/0619; G06F 3/0659; G06F 3/0673; G11C 11/40615

(57) ABSTRACT

Methods, systems, and devices for self-refresh exit detection for memory devices are described. The described techniques provide for a memory system to indicate whether the memory system is in a self-refresh mode or not. The memory system may initiate a self-refresh operation for one or more memory cells of the memory system. The memory system may set a mode register to a first value based on initiating the self-refresh operation. The first value of the mode register may indicate that the self-refresh operation is being executed. The memory system may determine whether to reset the mode register to a second value based on a status of the self-refresh operation. The second value of the mode register may indicate that the self-refresh operation is complete. A host system may poll the mode register to determine the status of the self-refresh operation at the memory system.

### CROSS REFERENCE

The present application for patent claims priority to U.S. Patent Application No. 63/619,179 by Uribe et al., entitled “SELF-REFRESH EXIT DETECTION FOR MEMORY DEVICES,” filed Jan. 9, 2024, which is assigned to the assignee hereof, and which is expressly incorporated by reference in its entirety herein.

### TECHNICAL FIELD

The following relates to one or more systems for memory, including self-refresh exit detection for memory devices.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports self-refresh exit detection for memory devices in accordance with examples as disclosed herein.

FIG. 2 shows an example of an architecture that supports self-refresh exit detection for memory devices in accordance with examples as disclosed herein.

FIG. 3 shows an example of a process flow that supports self-refresh exit detection for memory devices in accordance with examples as disclosed herein.

FIG. 4 shows a block diagram of a memory system that supports self-refresh exit detection for memory devices in accordance with examples as disclosed herein.

FIG. 5 shows a block diagram of a host system that supports self-refresh exit detection for memory devices in accordance with examples as disclosed herein.

FIGS. 6 and 7 show flowcharts illustrating a method or methods that support self-refresh exit detection for memory devices in accordance with examples as disclosed herein.

### DETAILED DESCRIPTION

A memory system may perform refresh operations on one or more rows of memory cells at the memory system, which may improve a reliability of data stored by the corresponding rows of memory cells. In some cases, the memory system may execute refresh operations based on or in response to receiving one or more refresh commands from a host system. Additionally, or alternatively, the memory system may execute refresh operations based on or in response to internally-generated refresh commands. For example, the memory system may enter a self-refresh state and execute one or more refresh operations (e.g., in response to internally-generated one or more refresh commands) on the rows of memory cells, for example, according to a refresh rate. In some examples, the memory system may experience one or more faults in circuitry that facilitates the one or more self-refresh operations, such that the memory system may be unable to exit or complete a self-refresh operation. If the memory system is stuck in a self-refresh operation (e.g., is unable to exit or complete a self-refresh operation), the memory system may not receive or be able to execute other access commands. A failure to execute a write command or a read command may be associated with increased error rates and reduced reliability, among other examples. In some cases, the memory system may support functional safety applications (e.g., automotive functional safety), which may be associated with one or more failure in time (FIT) constraints, among other constraints or related parameters. However, faults in receiving or executing access commands and failing to detect such faults may result in the memory system failing to satisfy FIT constraints, thereby limiting a performance of the memory system, among other challenges.

Techniques described herein provide for the memory system to indicate whether a self-refresh operation is being executed by the memory system. For example, the memory system may include or be coupled with one or more components or other aspects configured to store, act as, or otherwise be related to a self-refresh flag, which may be or include a mode register, a pin, or some other data structure that indicates a status of the self-refresh operation. The memory system may set the mode register to a first value (e.g., a default value, a value of zero) in response to initiating the self-refresh operation. The memory system may monitor a status of the self-refresh operation, and may reset the mode register to a second value (e.g., a value of one) in response to exiting or otherwise completing the self-refresh operation. A host device may poll the mode register to determine whether the memory system is in a self-refresh mode before issuing an access command. The host device may determine whether to issue the access command based on the value of the mode register. Additionally, or alternatively, the host device may issue an access command to the memory system and may subsequently monitor the value of the mode register to determine whether the access command was executed successfully. In some examples, if the mode register indicates that the memory system is in the self-refresh mode for a threshold time period, the host device may issue a command for the memory device to exit an operation, application, or mode in order to exit the self-refresh operation. The memory system may thereby indicate whether the memory system is in a self-refresh mode, which may provide for the host device to determine whether an access operation will be executed successfully. Although described in the context of self-refresh, it is to be understood that a similar indication may be supported for any refresh operation or other operations performed by the memory system.

In addition to applicability in memory systems as described herein, techniques for valid write operation detection for memory devices may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing failure rates for write commands and read commands due to faults in execution, which may reduce or mitigate latency associated with recovering lost or improperly stored data, among other benefits.

In addition to applicability in memory systems as described herein, techniques for valid write operation detection for memory devices may be generally implemented to support edge computing applications. Edge computing is a distributed computing paradigm that brings computation and data storage closer to the sources of data than traditional cloud services. As the use of edge computing to provide computing, storage, and networking services at locations that are geographically closer to end users increases, many devices and systems may benefit from improved processing, performance, and storage at edge devices. For example, increasing memory density, capacity, and processing power of edge devices may decrease a reliance on the devices to remote computing or devices, which may otherwise increase latency of operations performed at the devices. Implementing the techniques described herein may support edge computing techniques by reducing failure rates for write commands and read commands due to faults in execution at edge devices, among other benefits.

Features of the disclosure are illustrated and described in the context of systems and architectures. Features of the disclosure are further illustrated and described in the context of a process flow and flowcharts.

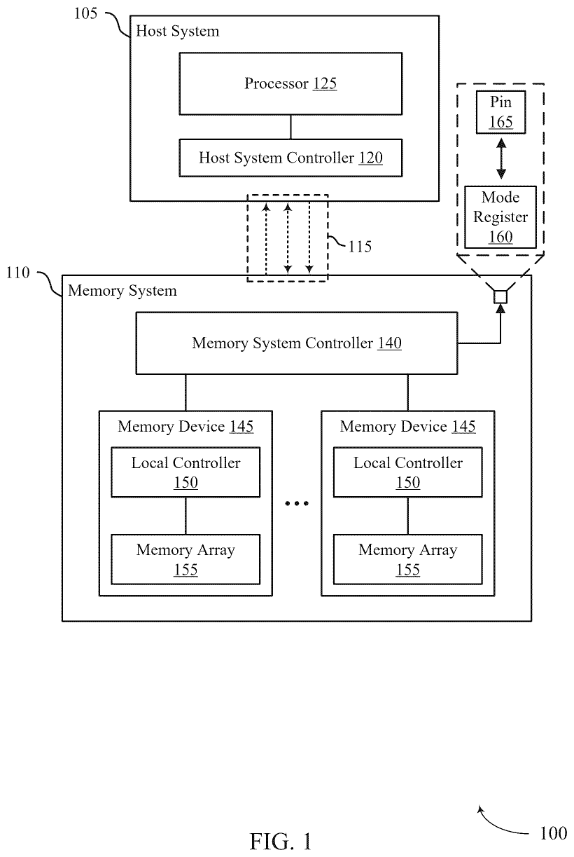

FIG. 1 illustrates an example of a system 100 that supports self-refresh exit detection for memory devices in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some examples of the system 100, the memory system 110 may perform refresh operations on one or more rows of memory cells at the memory system 110, which may improve a reliability of data stored by the corresponding rows of memory cells. In some cases, the memory system 110 may execute refresh operations in response to receiving one or more refresh commands from the host system 105. Additionally, or alternatively, the memory system 110 may execute refresh operations based on internally-generated refresh commands. For example, the memory system 110 may enter a self-refresh state (e.g., mode) and execute refresh operations (e.g., in response to internally-generated refresh commands) on the rows of memory cells according to a refresh rate. In some examples, the memory system 110 may experience one or more faults in circuitry that facilitates the self-refresh operations, such that the memory system 110 may be unable to exit or complete a self-refresh operation. If the memory system 110 is stuck in a self-refresh mode, the memory system 110 may not receive and execute other access commands. A failure to execute a write command or a read command may be associated with increased error rates and reduced reliability, among other examples.

Techniques described herein provide for the memory system 110 to set a flag to indicate whether a self-refresh operation is being executed by the memory system 110. For example, the memory system 110 may include or may be coupled with one or more components or other aspects configured to store, act as, or otherwise be related to a self-refresh flag. The self-refresh flag may, in some examples, be or include a mode register 160, a pin 165, or some other data structure that indicates a status of the self-refresh operation. The memory system 110 may set the mode register 160 to a first value (e.g., a default value, a value of zero) in response to initiating the self-refresh operation. The memory system 110 may monitor a status of the self-refresh operation, and may reset the mode register 160 to a second value (e.g., a value of one) in response to exiting or otherwise completing the self-refresh operation. Additionally, or alternatively, in some examples, the memory system 110 may signal the status of the self-refresh operation (e.g., to the host system 105), for example, via a pin 165, which may be an example of a DSF pin, or an alert pin, or some other type of pin. The host system 105 may poll the mode register 160 (e.g., and/or the pin 165) to determine whether the memory system 110 is in a self-refresh mode before issuing an access command. The host system 105 may determine whether to issue the access command based on the value of the mode register 160. Additionally, or alternatively, the host system 105 may issue an access command to the memory system 110 and may subsequently monitor the value of the mode register 160 to determine whether the access command was executed successfully. In some examples, if the mode register 160 indicates that the memory system 110 is in the self-refresh mode for a threshold time period, the host system 105 may issue a command for a memory device 145 of the memory system 110 to exit an application or mode in order to exit the self-refresh operation. The memory system 110 may thereby indicate whether the memory system 110 is in a self-refresh mode, which may provide for the host system 105 to determine whether an access operation will be executed successfully. Although described in the context of self-refresh, it is to be understood that a similar indication may be supported for any refresh or other operations performed by the memory system 110.

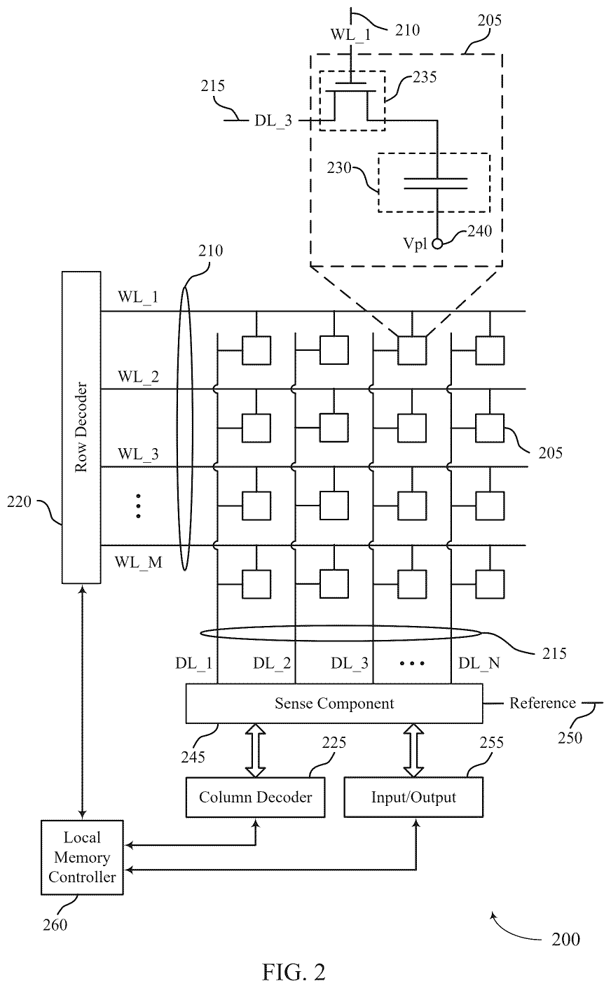

FIG. 2 illustrates an example of an architecture 200 (e.g., a memory architecture) that supports self-refresh exit detection for memory devices in accordance with examples as disclosed herein. The architecture 200 may be implemented in a memory system 110 or one or more components thereof (e.g., memory device 145). Aspects of the architecture 200 may be referred to as or implemented in a semiconductor component, such as a memory die.

The architecture 200 includes memory cells 205 that are programmable to store information. In some examples, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). Memory cells 205 may be arranged in an array, such as in a memory array 155.

In the example of architecture 200, a memory cell 205 may include a storage component, such as capacitor 230, and a selection component 235 (e.g., a cell selection component, a transistor). A capacitor 230 may be a dielectric capacitor or a ferroelectric capacitor. A node of the capacitor 230 may be coupled with a voltage source 240, which may be a cell plate reference voltage, such as Vpl, or may be a ground voltage, such as Vss. A charge stored by a memory cell 205 (e.g., by a capacitor 230) may be representative of a programmed state. Other memory architectures that support the techniques described herein may implement different types or arrangements of storage components and associated circuitry (e.g., with or without a selection component).

The architecture 200 may include various arrangements of access lines, such as word lines 210 and digit lines 215. An access line may be a conductive line that is coupled with a memory cell 205, and may be used to perform access operations on the memory cell 205. Word lines 210 may be referred to as row lines, and digit lines 215 may be referred to as column lines or bit lines, among other nomenclature. Memory cells 205 may be positioned at intersections of access lines, and an intersection may be referred to as an address of a memory cell 205.

In some architectures, a word line 210 may be coupled with a gate of a selection component 235 of a memory cell 205, and may be operable to control (e.g., switch, modulate a conductivity of) the selection component 235. A digit line 215 may be operable to couple a memory cell 205 with a sense component 245. In some architectures, a memory cell 205 (e.g., a capacitor 230) may be coupled with a digit line 215 during portions of an access operation. For example, a word line 210 and a selection component 235 of a memory cell 205 may be operable to couple or isolate a capacitor 230 of the memory cell 205 with a digit line 215.

Operations such as reading and writing may be performed on memory cells 205 by activating (e.g., applying a voltage to) access lines such as a word line 210 or a digit line 215. Accessing the memory cells 205 may be controlled through a row decoder 220, or a column decoder 225, or a combination thereof. For example, a row decoder 220 may receive a row address (e.g., from a local memory controller 260) and activate a word line 210 based on a received row address, and a column decoder 225 may receive a column address and activate a digit line 215 based on a received column address. Selecting or deselecting a memory cell 205 may include activating or deactivating a selection component 235 using a word line 210. For example, a capacitor 230 may be isolated from a digit line 215 when the selection component 235 is deactivated, and the capacitor 230 may be coupled with the digit line 215 when the selection component 235 is activated.

A sense component 245 may be operable to detect a state (e.g., a charge) stored by a capacitor 230 of a memory cell 205 and determine a logic state of the memory cell 205 based on the stored state. A sense component 245 may include one or more sense amplifiers to amplify or otherwise convert a signal resulting from accessing the memory cell 205. The sense component 245 may compare a signal detected from the memory cell 205 with a reference 250 (e.g., a reference voltage). The detected logic state of the memory cell 205 may be provided as an output of the sense component 245 (e.g., via an input/output 255), and may indicate the detected logic state to another component of a memory system 110 that implements the architecture 200.

The local memory controller 260 may control the accessing of memory cells 205 through the various components (e.g., a row decoder 220, a column decoder 225, a sense component 245), and may be an example of or otherwise included in a local controller 150, or a memory system controller 140, or both. In some examples, one or more of a row decoder 220, a column decoder 225, and a sense component 245 may be co-located with or included in the local memory controller 260. The local memory controller 260 may be operable to receive commands or data from one or more different controllers (e.g., a host system controller 120, a memory system controller 140), translate the commands or the data into information that can be used by the architecture 200, initiate or control one or more operations of the architecture 200, and communicate data from the architecture 200 to a host (e.g., a host system 105) based on performing the one or more operations.

The local memory controller 260 may be operable to perform one or more access operations on one or more memory cells 205 of the architecture 200. Examples of an access operation may include a write operation, a read operation, a refresh operation, a precharge operation, or an activate operation, among others. In some examples, an access operation may be performed by or otherwise coordinated by the local memory controller 260 in response to one or more access commands (e.g., from a host system 105). The local memory controller 260 may be operable to perform other access operations not listed here or other operations related to the operating of the architecture 200 that are not directly related to accessing the memory cells 205.

To support an access operation, a local memory controller 260 may identify a target memory cell 205 on which to perform the access operation, which may be associated with identifying a target word line 210 and a target digit line 215 coupled with the target memory cell 205 (e.g., an address of the target memory cell 205). The local memory controller 260 may control activating the target word line 210 and the target digit line 215 to access the target memory cell 205. During a write operation, the local memory controller 260 may control the application of a signal (e.g., a write pulse, a write voltage) to the target digit line 215 to store a specific state (e.g., a charge, in a capacitor 230) of the memory cell 205. The signal used as part of the write operation may include one or more voltage levels applied to the target memory cell 205 (e.g., via the target digit line 215) over one or more respective durations. During a read operation, the target memory cell 205 may transfer a signal (e.g., charge, voltage) to the sense component 245 based on activating the target word line 210 and the target digit line. The local memory controller 260 may activate the sense component 245 (e.g., initiate latching a sense amplifier of the sense component 245), which may include comparing the signal transferred from the memory cell 205 to a reference (e.g., the reference 250). Based on the comparison, the sense component 245 may determine a logic state that is stored on the memory cell 205.

In some examples of the architecture 200 as described herein, a memory system may enter a self-refresh mode to execute one or more self-refresh operations for one or more memory cells 205. The memory system may indicate whether the memory system is in self-refresh mode by, for example, setting a self-refresh flag, which may be or relate to a mode register, a pin, or some other data structure that indicates a status of the self-refresh operation, as described with reference to FIG. 1. The memory system may set the mode register to a first value (e.g., a default value, a value of zero) in response to initiating the self-refresh operation. The memory system may monitor a status of the self-refresh operation, and may reset the mode register to a second value (e.g., a value of one) in response to exiting or otherwise completing the self-refresh operation. A host device may poll the mode register to determine whether the memory system is in a self-refresh mode before issuing an access command. The host device may determine whether to issue the access command based on the value of the mode register. Additionally, or alternatively, the memory system may send an indication to the host device that indicates a status of the memory system being in a self-refresh mode, another mode, or one or more other conditions or statuses. Additionally, or alternatively, the host device may issue an access command to the memory system and may subsequently monitor the value of the mode register to determine whether the access command was executed successfully. In some examples, if the mode register indicates that the memory system is in the self-refresh mode for a threshold time period, the host device may issue a command for the memory device to exit an application or mode in order to exit the self-refresh operation. The memory system may thereby indicate whether the memory system is in a self-refresh mode, which may provide for the host device to determine whether an access operation will be executed successfully. Although described in the context of self-refresh, it is to be understood that a similar indication may be supported for any refresh or other operations performed by the memory system.

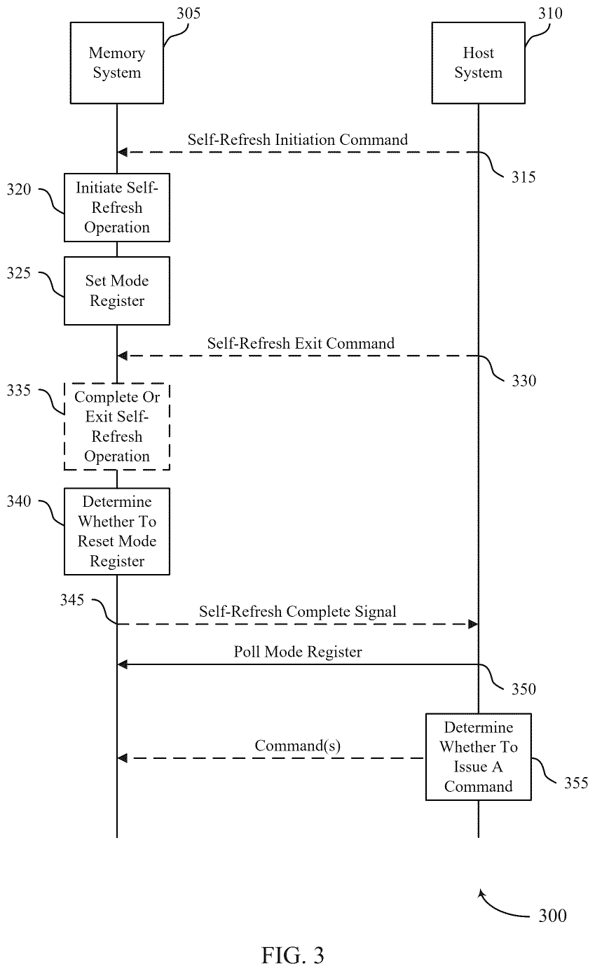

FIG. 3 shows an example of a process flow 300 that supports self-refresh exit detection for memory devices in accordance with examples as disclosed herein. The process flow 300 may implement, or be implemented by, one or more aspects of the system 100 and the architecture 200. For example, the process flow 300 may depict an example of signaling between a memory system 305 and a host system 310, which may be examples of corresponding aspects described with reference to FIG. 1. The process flow 300 may support the memory system 305 indicating a status of a self-refresh operation to refresh data in one or more memory cells of the memory system 305, which may be examples of memory cells 205 described with reference to FIG. 2. Alternative examples of the following may be implemented, where some processes are performed in a different order than described or are not performed. In some cases, processes may include additional features not mentioned below, or further processes may be added.

At 315, in some examples, the host system 310 may transmit a self-refresh initiation command to the memory system 305. The self-refresh initiation command may instruct or otherwise indicate to the memory system 305 to perform a self-refresh operation for one or more memory cells. In some examples, the self-refresh initiation command may be transmitted periodically, or based on one or more conditions or parameters associated with the one or more memory cells, an application being executed by the memory system 305, or one or more other triggers or conditions, or any combination thereof.

At 320, the memory system 305 may initiate the self-refresh operation. That is, the memory system 305 may enter a self-refresh mode and may start to refresh data in one or more target memory cells of a memory die of the memory system. In some examples, the self-refresh may include reading data from the one or more memory cells and writing refreshed data back to the one or more memory cells.

At 325, the memory system 305 may set a mode register (or some other location) of the memory system 305 to a first value in response to (e.g., based on) initiating the self-refresh operation. In some examples, the memory system 305 may set the mode register (or the some other location) to the first value before, concurrent with (e.g., at least partially overlapping with), or at the same time as initiating the self-refresh operation. The mode register may represent an example of a mode register 160 as described with reference to FIG. 1. In some examples, the mode register may be referred to as a self-refresh flag or a self-refresh indication. The mode register may be coupled with the memory system 305, the host system 310, or both. The value of the mode register may indicate whether the memory system 305 is in the self-refresh mode or not. Setting the mode register to the first value may include the memory system 305 refraining from driving an output of the mode register. For example, the first value may be a value of zero, or a default or ground value.

At 330, in some examples, the host system 310 may transmit a self-refresh exit command to the memory system 305. The self-refresh exit command may instruct the memory system 305 to exit the self-refresh mode. That is, the host system 310 may force the memory system 305 to exit self-refresh, regardless of whether the self-refresh operation is complete or not. In some examples, the host system 310 may poll the mode register at the memory system 305, and the host system 310 may transmit the self-refresh exit command if the mode register is set to the first value for more than a threshold time period, which may indicate that the memory system 305 is stuck in self-refresh, in some examples.

At 335, the memory system 305 may either complete the self-refresh operation or exit the self-refresh operation prior to completion. In some examples, the memory system 305 may successfully complete the self-refresh operation autonomously. In some other cases, the memory system 305 may exit the self-refresh operation prior to completion based on, for example, the self-refresh exit command at 330, or based on one or more other conditions or parameters associated with the self-refresh operation, an application executing at the memory system 305, or any combination thereof.

At 340, the memory system 305 may determine whether to reset the mode register to a second value. The memory system 305 may determine whether to reset the mode register from the first value to the second value based on a status of the self-refresh operation. The second value of the mode register may indicate that the memory system 305 is not in the self-refresh mode (e.g., the self-refresh operation is complete or has been exited).

In some examples, at 340, the memory system 305 may determine to maintain the first value of the mode register based on the status of the self-refresh operation being pending. That is, if the memory system 305 is still in self-refresh mode, the memory system 305 may not reset the mode register. Maintaining the first value may include the memory system 305 refraining from driving an output associated with the mode register, such that the value of the mode register remains at a ground or default value. Thus, if the memory system 305 remains in self-refresh mode, the memory system 305 may automatically maintain the first value of the mode register based on the memory system 305 being unable to perform any other operations different than the self-refresh operation.

Additionally, or alternatively, in some examples, at 340, the memory system 305 may determine to reset the mode register to the second value based on the status of the self-refresh operation being complete. That is, the memory system 305 may reset the mode register to the second value if the memory system 305 completes the self-refresh operation or has otherwise exited the self-refresh operation. In response to the completion or exit from the self-refresh operation, the memory system 305 may set the mode register to the second value, which may be a high value or a value of one, in some examples. The memory system 305 may thereby drive an output associated with the mode register during time periods when the memory system 305 is not in the self-refresh mode, and the memory system 305 may refrain from driving the output associated with the mode register during time periods when the memory system 305 is in the self-refresh mode.

At 345, in some examples, the memory system 305 may transmit a self-refresh complete signal to the host system 310. The memory system 305 may transmit the signal to the host system 310 via a pin, such as the pin 165 described with reference to FIG. 1. The memory system 305 may transmit the self-refresh complete signal in response to (e.g., based on) the memory system 305 completing or otherwise exiting the self-refresh operation. In some examples, the mode register may be coupled with the pin, and the pin may be set automatically based on the mode register transitioning from the first value to the second value. Additionally, or alternatively, the memory system 305 may set the mode register to the second value and may set the pin before, concurrent with (e.g., at least partially overlapping with), at the same time as, or after setting the mode register to the second value.

In some examples, the memory system 305 may refrain from setting the mode register and may instead alert the host system 310 of the status of the refresh operation via the pin. That is, the memory system may, at 340, determine whether to transmit an indication via the pin rather than determine whether to set the mode register. The self-refresh complete signal may correspond to the pin being biased from a first voltage to a second voltage. In some examples, the pin may be an example of a decode status flag (DSF) pin (e.g., a direct media interface (DMI) I/O pin used during a read operation as DSF+ to output a status or flag a failure before data bursts begin) or an alert pin (e.g., a double data rate 4 (DDR4) and/or a low-power DDR 6 (LPDDR6) alert pin that is output to indicate a failure status), or some other type of pin that is coupled with the memory system 305 and the host system 310.

At 350, the host system 310 may poll the mode register. The host system 310 may poll the mode register periodically, randomly, or in response to one or more conditions, among other examples. In some cases, the host system 310 may identify the value of the mode register based on polling the mode register, which may indicate the status of the self-refresh operation at the memory system 305. For example, the value of the mode register may indicate, to the host system 310, whether the memory system 305 is in a self-refresh mode or not.

In some examples, the host system 310 may issue an access command to the memory system 305 and may subsequently poll the mode register. The value of the mode register may indicate whether the access command was successfully received, decoded, and executed by the memory system 305. For example, if the mode register is set to the first value, the memory system 305 may be in the self-refresh mode, and may not have received, decoded, and/or executed the access command successfully. The host system 310 may use this information to determine next steps. In some examples, the host system 310 may re-transmit the command or may reset one or more operational parameters to assume the command was not transmitted. If the mode register is set to the second value, the host system 310 may determine that the memory system 305 likely executed the command, because the memory system 305 was not in the self-refresh mode.

At 355, the host system 310 may determine, based on the value of the mode, whether to issue a command to the memory system 305. For example, if the mode register is set to the second value, which indicates that the memory system 305 is not in the self-refresh mode (e.g., the self-refresh operation is complete), the host system 310 may issue one or more access commands, such as a read command, a write command, or both to the memory system 305. The host system 310 may determine that the memory system 305 will be able to receive, decode, and perform the commands based on the memory system 305 not being in the self-refresh mode.

In some other examples, if the mode register is set to the first value, which indicates that the memory system 305 is in the self-refresh mode, the host system 310 may determine not to issue an access command to the memory system 305. The host system 310 may instead determine to transmit the self-refresh exit command that triggers an exit from the self-refresh operation for the memory die of the memory system. In some examples, the host system 310 may issue an application exit command, an autonomous driving exit command, or some other command that triggers the memory system 305 to exit self-refresh mode or otherwise reset based on the mode register indicating that the memory system 305 is in the self-refresh mode. For example, the memory system 305 may perform self-refresh as part of executing an application or operating in an autonomous driving mode. As such, the exit commands may trigger the memory system 305 to exit the corresponding application and/or mode, which may cause the memory system 305 to also exit the self-refresh mode. Additionally, or alternatively, the host system 310 may determine to issue an access command or other type of command to a second memory die of the memory system 305 based on the mode register indicating that a first memory die of the memory system 305 is in the self-refresh mode. That is, the host system 310 may target another location in memory that is not currently being refreshed.

In some examples, the host system 310 may determine whether to issue the one or more various commands after a threshold time period. That is, if the host system 310 determines that the mode register has been set to the first value for more than a threshold time period, the host system 310 may determine that the memory system 305 is stuck in self-refresh, and the host system 310 may issue a command to another memory location, or a self-refresh exit command, an application exit command, or the like. Although described with reference to the mode register, it is to be understood that the host system 310 may determine whether to issue the command(s) based on any signals received via the pin.

By adjusting the value of the mode register, biasing the pin, or both according to the status of the self-refresh operation, the memory system 305 may improve detection of faults in command execution, which may support the memory system 305 satisfying one or more FIT rate constraints (e.g., a unit representing failure rates and how many failures occur every 10⁹ hours). For example, the memory system 305 may be operable to perform a functional safety application, such as an automotive functional safety application, which may be associated with a FIT rate constraint, such as <0.4 FIT undetected (e.g., for a stand-alone DRAM device in automotive safety integrity level (ASIL) D). In some examples, a FIT for failure to exit self-refresh may be around 0.6 FIT, or some other FIT, where a first portion of the FIT (e.g., around 0.35 FIT, or some other portion) may be associated with read command failure, and a second portion of the FIT (e.g., around 0.15 FIT, or some other portion) may be associated with write command failure.

In some examples, one or more error correcting code (ECC) schemes implemented by the memory system 305, such as host inline ECC or link ECC, may be unsuitable to detect faults in command execution (e.g., faults in decoding, initiating, or completing a command). For example, such ECC schemes may be configured to detect whether values stored to a memory array are correct (e.g., detect data corruption). In such examples, if the memory system 305 fails to execute a write command due to, for example, the memory system 305 being in the self-refresh mode, the memory system 305 may fail to overwrite old data with the new data indicated in the write command. However, if the old data does not contain errors (e.g., is not corrupted), the ECC schemes may detect no errors in the data and the host system 310 may remain unaware of the command execution fault. In some other examples, if the memory system 305 fails to execute a read command, there may be no drive at a termination or high resistance output, which may be detectable by host inline ECC, in some examples, but is not guaranteed. In systems with ground terminated outputs, a failure to execute a read command may be detectable with additional host ECC implementation (e.g., address seeding, All-0 Detect, or some other detection technique). Thus, the memory system 305 may improve command execution fault detection by indicating a status of a self-refresh operation via the mode register and/or the pin, which may support the memory system 305 satisfying FIT rate constraints for one or more applications (such as automotive functional safety applications).

The techniques described herein may thereby provide for the memory system 305 and the host system 310 to improve detection of command execution failures due to self-refresh, which may support the memory system 305 satisfying FIT rate constraints and mitigating data loss, among other examples.

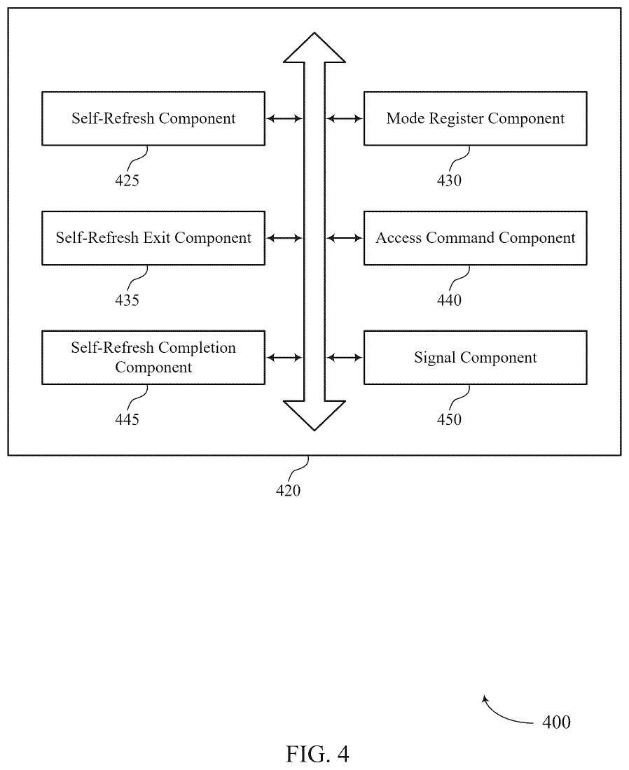

FIG. 4 shows a block diagram 400 of a memory system 420 that supports self-refresh exit detection for memory devices in accordance with examples as disclosed herein. The memory system 420 may be an example of aspects of a memory system as described with reference to FIGS. 1 through 3. The memory system 420, or various components thereof, may be an example of means for performing various aspects of self-refresh exit detection for memory devices as described herein. For example, the memory system 420 may include a self-refresh component 425, a mode register component 430, a self-refresh exit component 435, an access command component 440, a self-refresh completion component 445, a signal component 450, or any combination thereof. Each of these components, or components of subcomponents thereof (e.g., one or more processors, one or more memories), may communicate, directly or indirectly, with one another (e.g., via one or more buses).

The self-refresh component 425 may be configured as or otherwise support a means for initiating a self-refresh operation for a memory die of a memory system. The mode register component 430 may be configured as or otherwise support a means for setting a mode register to a first value based at least in part on initiating the self-refresh operation, where the first value of the mode register indicates that the self-refresh operation is being executed. In some examples, the mode register component 430 may be configured as or otherwise support a means for determining whether to reset the mode register to a second value based at least in part on a status of the self-refresh operation, where the second value of the mode register indicates that the self-refresh operation is complete.

In some examples, the self-refresh component 425 may be configured as or otherwise support a means for completing the self-refresh operation for the memory die. In some examples, the mode register component 430 may be configured as or otherwise support a means for resetting the mode register to the second value based at least in part on completing the self-refresh operation, where determining whether to reset the mode register to the second value includes determining to reset the mode register to the second value based at least in part on completing the self-refresh operation.

In some examples, the self-refresh exit component 435 may be configured as or otherwise support a means for receiving a self-refresh exit command. In some examples, the self-refresh exit component 435 may be configured as or otherwise support a means for exiting the self-refresh operation prior to completion based at least in part on the self-refresh exit command. In some examples, the mode register component 430 may be configured as or otherwise support a means for resetting the mode register to the second value based at least in part on exiting the self-refresh operation, where determining whether to reset the mode register to the second value includes determining to reset the mode register to the second value based at least in part on exiting the self-refresh operation.

In some examples, receiving the self-refresh exit command is based at least in part on the mode register being set to the first value for at least a threshold time.

In some examples, the mode register component 430 may be configured as or otherwise support a means for resetting the mode register to the second value based at least in part on exiting the self-refresh operation or completing the self-refresh operation. In some examples, the access command component 440 may be configured as or otherwise support a means for receiving one or more access commands based at least in part on resetting the mode register to the second value, the one or more access commands including a read command, a write command, or both.

In some examples, the mode register component 430 may be configured as or otherwise support a means for maintaining the first value of the mode register based at least in part on the status of the self-refresh operation being pending. In some examples, the access command component 440 may be configured as or otherwise support a means for receiving, at the memory system based at least in part on the mode register being set to the first value, an access command for a second memory die of the memory system.

In some examples, the mode register component 430 may be configured as or otherwise support a means for maintaining the first value of the mode register based at least in part on the status of the self-refresh operation being pending, where maintaining the first value of the mode register includes refraining from driving an output associated with the mode register.

In some examples, the self-refresh component 425 may be configured as or otherwise support a means for receiving a self-refresh initiation command, where initiating the self-refresh operation for the memory die is based at least in part on the self-refresh initiation command.

In some examples, the self-refresh completion component 445 may be configured as or otherwise support a means for completing the self-refresh operation for the memory die. In some examples, the signal component 450 may be configured as or otherwise support a means for transmitting, via a pin, a signal that indicates the self-refresh operation is complete.

In some examples, the mode register component 430 may be configured as or otherwise support a means for setting the mode register to the second value based at least in part on completing the self-refresh operation, where transmitting the signal is based at least in part on the second value of the mode register.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

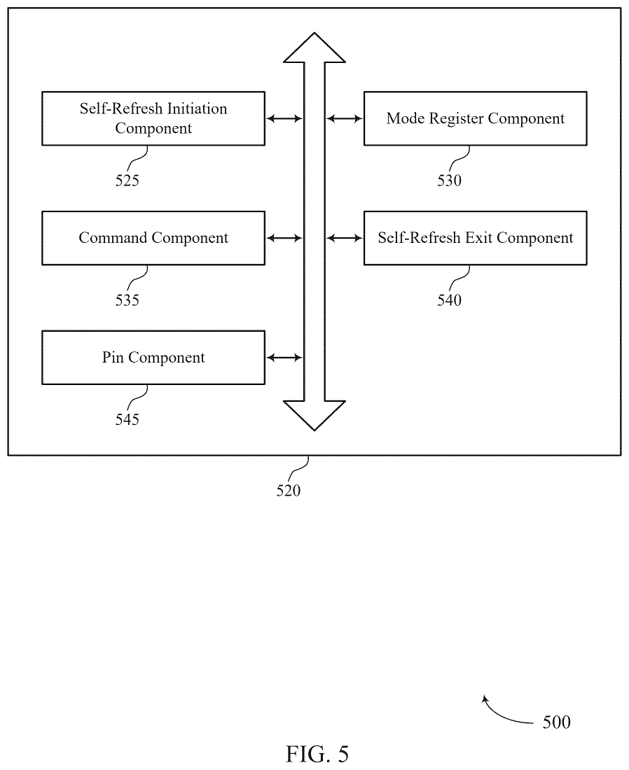

FIG. 5 shows a block diagram 500 of a host system 520 that supports self-refresh exit detection for memory devices in accordance with examples as disclosed herein. The host system 520 may be an example of aspects of a host system as described with reference to FIGS. 1 through 3. The host system 520, or various components thereof, may be an example of means for performing various aspects of self-refresh exit detection for memory devices as described herein. For example, the host system 520 may include a self-refresh initiation component 525, a mode register component 530, a command component 535, a self-refresh exit component 540, a pin component 545, or any combination thereof. Each of these components, or components of subcomponents thereof (e.g., one or more processors, one or more memories), may communicate, directly or indirectly, with one another (e.g., via one or more buses).

The self-refresh initiation component 525 may be configured as or otherwise support a means for transmitting, from a host system, a self-refresh initiation command, where the self-refresh initiation command is for triggering a self-refresh operation for at least a memory die of a memory system. The mode register component 530 may be configured as or otherwise support a means for polling a mode register of the memory system, where a value of the mode register indicates a status of the self-refresh operation at the memory system. The command component 535 may be configured as or otherwise support a means for determining, based at least in part on the value of the mode register, whether to issue a command to the memory system.

In some examples, the command component 535 may be configured as or otherwise support a means for issuing the command to the memory system based at least in part on the value of the mode register being a second value that indicates the self-refresh operation is complete, where the command includes a read command or a write command.

In some examples, the command component 535 may be configured as or otherwise support a means for issuing, to the memory system before polling the mode register, a first command. In some examples, the command component 535 may be configured as or otherwise support a means for determining whether the first command has been executed based at least in part on the value of the mode register.

In some examples, the self-refresh exit component 540 may be configured as or otherwise support a means for transmitting, from the host system, a self-refresh exit command that triggers an exit from the self-refresh operation for the memory die of the memory system, where the value of the mode register is a second value that indicates the self-refresh operation has been exited based at least in part on the self-refresh exit command.

In some examples, transmitting the self-refresh exit command is based at least in part on the value of the mode register being set to a first value for at least a threshold time. In some examples, the first value indicates that the self-refresh operation is being executed.

In some examples, the command component 535 may be configured as or otherwise support a means for issuing a second command for a second memory die of the memory system based at least in part on the value of the mode register being set to a first value, where the first value indicates that the self-refresh operation is being executed.

In some examples, the self-refresh exit component 540 may be configured as or otherwise support a means for issuing the command based at least in part on the value of the mode register being set to a first value for at least a threshold time, the command including an application exit command or an autonomous driving exit command, where the first value indicates that the self-refresh operation is being executed.

In some examples, the pin component 545 may be configured as or otherwise support a means for receiving, via a pin, an indication that the self-refresh operation is complete.

In some examples, the described functionality of the host system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the host system 520, or various components thereof, may be implemented at least in part by instructions (e.g., stored in memory, non-transitory computer-readable medium) executable by such at least one processor.

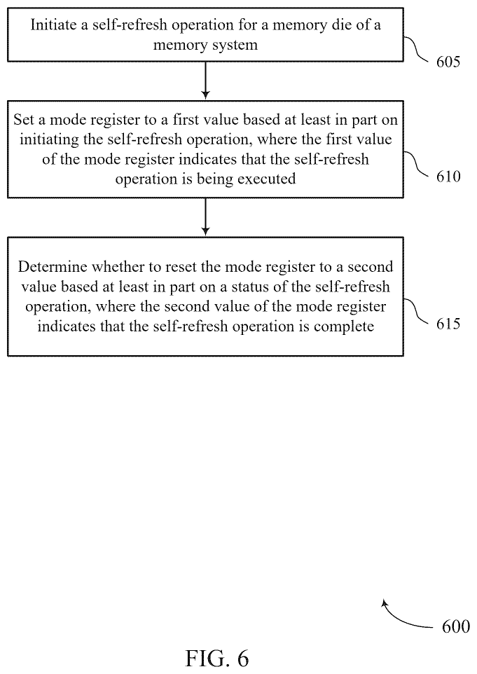

FIG. 6 shows a flowchart illustrating a method 600 that supports self-refresh exit detection for memory devices in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include initiating a self-refresh operation for a memory die of a memory system. In some examples, aspects of the operations of 605 may be performed by a self-refresh component 425 as described with reference to FIG. 4.

At 610, the method may include setting a mode register to a first value based at least in part on initiating the self-refresh operation, where the first value of the mode register indicates that the self-refresh operation is being executed. In some examples, aspects of the operations of 610 may be performed by a mode register component 430 as described with reference to FIG. 4.

At 615, the method may include determining whether to reset the mode register to a second value based at least in part on a status of the self-refresh operation, where the second value of the mode register indicates that the self-refresh operation is complete. In some examples, aspects of the operations of 615 may be performed by a mode register component 430 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for initiating a self-refresh operation for a memory die of a memory system; setting a mode register to a first value based at least in part on initiating the self-refresh operation, where the first value of the mode register indicates that the self-refresh operation is being executed; and determining whether to reset the mode register to a second value based at least in part on a status of the self-refresh operation, where the second value of the mode register indicates that the self-refresh operation is complete.

Aspect 2: The method, apparatus, or non-transitory computer-readable medium of aspect 1, further including operations, features, circuitry, logic, means, or instructions, or any combination thereof for completing the self-refresh operation for the memory die and resetting the mode register to the second value based at least in part on completing the self-refresh operation, where determining whether to reset the mode register to the second value includes determining to reset the mode register to the second value based at least in part on completing the self-refresh operation.

Aspect 3: The method, apparatus, or non-transitory computer-readable medium of any of aspects 1 through 2, further including operations, features, circuitry, logic, means, or instructions, or any combination thereof for receiving a self-refresh exit command; exiting the self-refresh operation prior to completion based at least in part on the self-refresh exit command; and resetting the mode register to the second value based at least in part on exiting the self-refresh operation, where determining whether to reset the mode register to the second value includes determining to reset the mode register to the second value based at least in part on exiting the self-refresh operation.

Aspect 4: The method, apparatus, or non-transitory computer-readable medium of aspect 3, where receiving the self-refresh exit command is based at least in part on the mode register being set to the first value for at least a threshold time.

Aspect 5: The method, apparatus, or non-transitory computer-readable medium of any of aspects 1 through 4, further including operations, features, circuitry, logic, means, or instructions, or any combination thereof for resetting the mode register to the second value based at least in part on exiting the self-refresh operation or completing the self-refresh operation and receiving one or more access commands based at least in part on resetting the mode register to the second value, the one or more access commands including a read command, a write command, or both.

Aspect 6: The method, apparatus, or non-transitory computer-readable medium of any of aspects 1 through 5, further including operations, features, circuitry, logic, means, or instructions, or any combination thereof for maintaining the first value of the mode register based at least in part on the status of the self-refresh operation being pending and receiving, at the memory system based at least in part on the mode register being set to the first value, an access command for a second memory die of the memory system.

Aspect 7: The method, apparatus, or non-transitory computer-readable medium of any of aspects 1 through 6, further including operations, features, circuitry, logic, means, or instructions, or any combination thereof for maintaining the first value of the mode register based at least in part on the status of the self-refresh operation being pending, where maintaining the first value of the mode register includes refraining from driving an output associated with the mode register.

Aspect 8: The method, apparatus, or non-transitory computer-readable medium of any of aspects 1 through 7, further including operations, features, circuitry, logic, means, or instructions, or any combination thereof for receiving a self-refresh initiation command, where initiating the self-refresh operation for the memory die is based at least in part on the self-refresh initiation command.

Aspect 9: The method, apparatus, or non-transitory computer-readable medium of any of aspects 1 through 8, further including operations, features, circuitry, logic, means, or instructions, or any combination thereof for completing the self-refresh operation for the memory die and transmitting, via a pin, a signal that indicates the self-refresh operation is complete.

Aspect 10: The method, apparatus, or non-transitory computer-readable medium of aspect 9, further including operations, features, circuitry, logic, means, or instructions, or any combination thereof for setting the mode register to the second value based at least in part on completing the self-refresh operation, where transmitting the signal is based at least in part on the second value of the mode register.

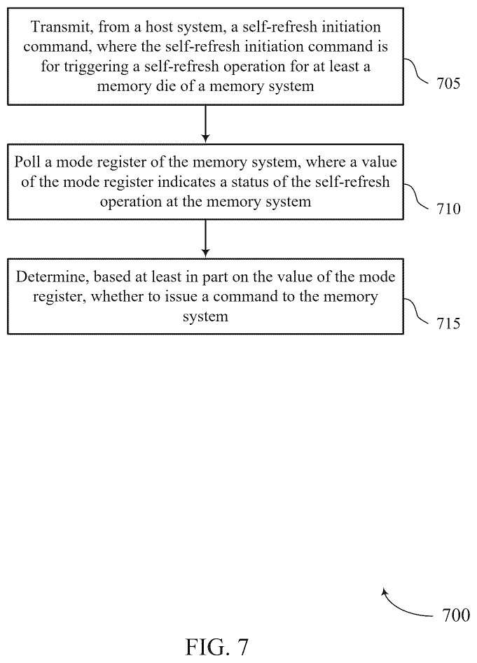

FIG. 7 shows a flowchart illustrating a method 700 that supports self-refresh exit detection for memory devices in accordance with examples as disclosed herein. The operations of method 700 may be implemented by a host system or its components as described herein. For example, the operations of method 700 may be performed by a host system as described with reference to FIGS. 1 through 3 and 5. In some examples, a host system may execute a set of instructions to control the functional elements of the device to perform the described functions. Additionally, or alternatively, the host system may perform aspects of the described functions using special-purpose hardware.

At 705, the method may include transmitting, from a host system, a self-refresh initiation command, where the self-refresh initiation command is for triggering a self-refresh operation for at least a memory die of a memory system. In some examples, aspects of the operations of 705 may be performed by a self-refresh initiation component 525 as described with reference to FIG. 5.

At 710, the method may include polling a mode register of the memory system, where a value of the mode register indicates a status of the self-refresh operation at the memory system. In some examples, aspects of the operations of 710 may be performed by a mode register component 530 as described with reference to FIG. 5.

At 715, the method may include determining, based at least in part on the value of the mode register, whether to issue a command to the memory system. In some examples, aspects of the operations of 715 may be performed by a command component 535 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 11: A method, apparatus, or non-transitory computer-readable medium including operations, features, circuitry, logic, means, or instructions, or any combination thereof for transmitting, from a host system, a self-refresh initiation command, where the self-refresh initiation command is for triggering a self-refresh operation for at least a memory die of a memory system; polling a mode register of the memory system, where a value of the mode register indicates a status of the self-refresh operation at the memory system; and determining, based at least in part on the value of the mode register, whether to issue a command to the memory system.

Aspect 12: The method, apparatus, or non-transitory computer-readable medium of aspect 11, further including operations, features, circuitry, logic, means, or instructions, or any combination thereof for issuing the command to the memory system based at least in part on the value of the mode register being a second value that indicates the self-refresh operation is complete, where the command includes a read command or a write command.

Aspect 13: The method, apparatus, or non-transitory computer-readable medium of any of aspects 11 through 12, further including operations, features, circuitry, logic, means, or instructions, or any combination thereof for issuing, to the memory system before polling the mode register, a first command and determining whether the first command has been executed based at least in part on the value of the mode register.

Aspect 14: The method, apparatus, or non-transitory computer-readable medium of any of aspects 11 through 13, further including operations, features, circuitry, logic, means, or instructions, or any combination thereof for transmitting, from the host system, a self-refresh exit command that triggers an exit from the self-refresh operation for the memory die of the memory system, where the value of the mode register is a second value that indicates the self-refresh operation has been exited based at least in part on the self-refresh exit command.

Aspect 15: The method, apparatus, or non-transitory computer-readable medium of aspect 14, where transmitting the self-refresh exit command is based at least in part on the value of the mode register being set to a first value for at least a threshold time and the first value indicates that the self-refresh operation is being executed.

Aspect 16: The method, apparatus, or non-transitory computer-readable medium of any of aspects 11 through 15, further including operations, features, circuitry, logic, means, or instructions, or any combination thereof for issuing a second command for a second memory die of the memory system based at least in part on the value of the mode register being set to a first value, where the first value indicates that the self-refresh operation is being executed.

Aspect 17: The method, apparatus, or non-transitory computer-readable medium of any of aspects 11 through 16, further including operations, features, circuitry, logic, means, or instructions, or any combination thereof for issuing the command based at least in part on the value of the mode register being set to a first value for at least a threshold time, the command including an application exit command or an autonomous driving exit command, where the first value indicates that the self-refresh operation is being executed.

Aspect 18: The method, apparatus, or non-transitory computer-readable medium of any of aspects 11 through 17, further including operations, features, circuitry, logic, means, or instructions, or any combination thereof for receiving, via a pin, an indication that the self-refresh operation is complete.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
initiate a self-refresh operation for a memory die of the memory system;
set a mode register to a first value based at least in part on initiating the self-refresh operation, wherein the first value of the mode register indicates that the self-refresh operation is being executed; and
determine whether to reset the mode register to a second value based at least in part on a status of the self-refresh operation, wherein the second value of the mode register indicates that the self-refresh operation is complete.

2. The memory system of claim 1, wherein the processing circuitry is further configured to cause the memory system to:
complete the self-refresh operation for the memory die; and
reset the mode register to the second value based at least in part on completing the self-refresh operation, wherein determining whether to reset the mode register to the second value comprises determining to reset the mode register to the second value based at least in part on completing the self-refresh operation.

3. The memory system of claim 1, wherein the processing circuitry is further configured to cause the memory system to:
receive a self-refresh exit command;
exit the self-refresh operation prior to completion based at least in part on the self-refresh exit command; and
reset the mode register to the second value based at least in part on exiting the self-refresh operation, wherein determining whether to reset the mode register to the second value comprises determining to reset the mode register to the second value based at least in part on exiting the self-refresh operation.

4. The memory system of claim 3, wherein receiving the self-refresh exit command is based at least in part on the mode register being set to the first value for at least a threshold time.

5. The memory system of claim 1, wherein the processing circuitry is further configured to cause the memory system to:
reset the mode register to the second value based at least in part on exiting the self-refresh operation or completing the self-refresh operation; and
receive one or more access commands based at least in part on resetting the mode register to the second value, the one or more access commands comprising a read command, a write command, or both.

6. The memory system of claim 1, wherein the processing circuitry is further configured to cause the memory system to:
maintain the first value of the mode register based at least in part on the status of the self-refresh operation being pending; and
receive, at the memory system based at least in part on the mode register being set to the first value, an access command for a second memory die of the memory system.

7. The memory system of claim 1, wherein the processing circuitry is further configured to cause the memory system to:
maintain the first value of the mode register based at least in part on the status of the self-refresh operation being pending, wherein maintaining the first value of the mode register comprises refraining from driving an output associated with the mode register.

8. The memory system of claim 1, wherein the processing circuitry is further configured to cause the memory system to:
receive a self-refresh initiation command, wherein initiating the self-refresh operation for the memory die is based at least in part on the self-refresh initiation command.

9. The memory system of claim 1, wherein the processing circuitry is further configured to cause the memory system to:
complete the self-refresh operation for the memory die; and
transmit, via a pin, a signal that indicates the self-refresh operation is complete.

10. The memory system of claim 9, wherein the processing circuitry is further configured to cause the memory system to:
set the mode register to the second value based at least in part on completing the self-refresh operation, wherein transmitting the signal is based at least in part on the second value of the mode register.

11. A host system, comprising:
one or more interfaces comprising one or more signal paths operable for communications with one or more memory systems; and
processing circuitry coupled with the one or more interfaces and configured to cause the host system to:
transmit, from the host system, a self-refresh initiation command, wherein the self-refresh initiation command is for triggering a self-refresh operation for at least a memory die of a memory system;
poll a mode register of the memory system, wherein a value of the mode register indicates a status of the self-refresh operation at the memory system; and
determine, based at least in part on the value of the mode register, whether to issue a command to the memory system.

12. The host system of claim 11, wherein the processing circuitry is further configured to cause the host system to:
issue the command to the memory system based at least in part on the value of the mode register being a second value that indicates the self-refresh operation is complete, wherein the command comprises a read command or a write command.

13. The host system of claim 11, wherein the processing circuitry is further configured to cause the host system to:
issue, to the memory system before polling the mode register, a first command; and
determine whether the first command has been executed based at least in part on the value of the mode register.

14. The host system of claim 11, wherein the processing circuitry is further configured to cause the host system to:
transmit, from the host system, a self-refresh exit command that triggers an exit from the self-refresh operation for the memory die of the memory system, wherein the value of the mode register is a second value that indicates the self-refresh operation has been exited based at least in part on the self-refresh exit command.

15. The host system of claim 14, wherein:
transmitting the self-refresh exit command is based at least in part on the value of the mode register being set to a first value for at least a threshold time; and
the first value indicates that the self-refresh operation is being executed.

16. The host system of claim 11, wherein the processing circuitry is further configured to cause the host system to:
issue a second command for a second memory die of the memory system based at least in part on the value of the mode register being set to a first value, wherein the first value indicates that the self-refresh operation is being executed.

17. The host system of claim 11, wherein the processing circuitry is further configured to cause the host system to:
issue the command based at least in part on the value of the mode register being set to a first value for at least a threshold time, the command comprising an application exit command or an autonomous driving exit command, wherein the first value indicates that the self-refresh operation is being executed.

18. The host system of claim 11, wherein the processing circuitry is further configured to cause the host system to:
receive, via a pin, an indication that the self-refresh operation is complete.

19. A non-transitory computer-readable medium storing code, the code comprising instructions executable by one or more processors to:
initiate a self-refresh operation for a memory die of a memory system;
set a mode register to a first value based at least in part on initiating the self-refresh operation, wherein the first value of the mode register indicates that the self-refresh operation is being executed; and
determine whether to reset the mode register to a second value based at least in part on a status of the self-refresh operation, wherein the second value of the mode register indicates that the self-refresh operation is complete.

20. The non-transitory computer-readable medium of claim 19, wherein the instructions are further executable by the one or more processors to:
complete the self-refresh operation for the memory die; and
reset the mode register to the second value based at least in part on completing the self-refresh operation, wherein determining whether to reset the mode register to the second value comprises determining to reset the mode register to the second value based at least in part on completing the self-refresh operation.

21. The non-transitory computer-readable medium of claim 19, wherein the instructions are further executable by the one or more processors to:
receive a self-refresh exit command;
exit the self-refresh operation prior to completion based at least in part on the self-refresh exit command; and
reset the mode register to the second value based at least in part on exiting the self-refresh operation, wherein determining whether to reset the mode register to the second value comprises determining to reset the mode register to the second value based at least in part on exiting the self-refresh operation.

22. A non-transitory computer-readable medium storing code, the code comprising instructions executable by one or more processors to:
transmit, from a host system, a self-refresh initiation command, wherein the self-refresh initiation command is for triggering a self-refresh operation for at least a memory die of a memory system;
poll a mode register of the memory system, wherein a value of the mode register indicates a status of the self-refresh operation at the memory system; and
determine, based at least in part on the value of the mode register, whether to issue a command to the memory system.

23. The non-transitory computer-readable medium of claim 22, wherein the instructions are further executable by the one or more processors to:
issue the command to the memory system based at least in part on the value of the mode register being a second value that indicates the self-refresh operation is complete, wherein the command comprises a read command or a write command.

24. The non-transitory computer-readable medium of claim 22, wherein the instructions are further executable by the one or more processors to:
issue, to the memory system before polling the mode register, a first command; and
determine whether the first command has been executed based at least in part on the value of the mode register.
